(19) United States
(12) Patent Application Publication
(10) Pub. No.: US 2025/0185405 A1
(43) Pub. Date: Jun. 5, 2025

(54) LIGHT DETECTING PIXEL USING VERTICAL GATES

(71) Applicant: STMICROELECTRONICS INTERNATIONAL N.V., Geneva (CH)

(72) Inventors: Bruno Henrique LOPES, Grenoble (FR); Pascal FONTENEAU, Theys (FR); Boris RODRIGUES GONCALVES, Theys (FR)

(21) Appl. No.: 18/524,939

(22) Filed: Nov. 30, 2023

(51) Int. Cl. H01L 27/146; G01S 7/4865

(52) U.S. Cl. CPC H10F 39/812; H10F 39/011; H10F 39/802; G01S 7/4865

(57) ABSTRACT

Various embodiments of the present disclosure provide systems, apparatuses, products, and methods for light detection. In various embodiments, a pixel for detecting light is provided. In various embodiments, the pixel includes a substrate configured to generate one or more carriers in response to an incident light beam, a first vertical gate and a second vertical gate disposed inside the substrate, a first vertical gate input electronically coupled to the first vertical gate and configured to receive a first gate control signal, and a second vertical gate input electronically coupled to the second vertical gate and configured to receive a second gate control signal. In various embodiments, the first and second vertical gates are configured to direct the one or more carriers to the first sensing node or the second sensing node using the first and second gate control signals.

### TECHNOLOGICAL FIELD

Example embodiments of the present disclosure relate generally to light detection, and more particularly to light detecting pixels.

### BACKGROUND

Light detecting pixels are used in various technologies for example in three-dimensional (3D) and two-dimensional (2D) imaging systems. New developments in the technologies that use light detecting pixels require the pixels to have improved performance. Applicant has identified many technical challenges and difficulties associated with light detecting pixels. Through applied effort, ingenuity, and innovation, Applicant has solved problems related to light detecting pixels by developing solutions embodied in the present disclosure, which are described in detail below.

### BRIEF SUMMARY

Various embodiments described herein relate to systems, apparatuses, products, and methods for light detection. In various embodiments, a pixel for detecting light is provided. In various embodiments, the pixel includes a substrate configured to generate one or more carriers in response to an incident light beam; a first vertical gate and a second vertical gate disposed inside the substrate, wherein the first and second vertical gates are configured to direct the one or more carriers to a first sensing node or a second sensing node; a first vertical gate input electronically coupled to the first vertical gate and configured to receive a first gate control signal; and a second vertical gate input electronically coupled to the second vertical gate and configured to receive a second gate control signal, wherein the first and second vertical gates are configured to direct the one or more carriers to the first sensing node or the second sensing node using the first and second gate control signals.

In various embodiments, the first vertical gate is configured to be activated using the first gate control signal and direct the one or more carriers to the first sensing node when activated; and the second vertical gate is configured to be activated using the second gate control signal and direct the one or more carriers to the second sensing node when activated.

In various embodiments, the first vertical gate is deactivated when the second vertical gate is activated; and the second vertical gate is deactivated when the first vertical gate is activated. In various embodiments, the first and second gate control signals include periodic waveforms and are complements of each other.

In various embodiments, the pixel includes a third vertical gate disposed inside the substrate; a fourth vertical gate disposed inside the substrate, wherein the first, second, third, and fourth vertical gates are configured to direct the one or more carriers to the first sensing node or the second sensing node; a third gate input electronically coupled to the third vertical gate and configured to receive a third gate control signal; and a fourth gate input electronically coupled to the fourth vertical gate and configured to receive a fourth gate control signal, wherein the first, second, third and fourth vertical gates are configured to direct the one or more carriers to the first sensing node or the second sensing node using the first, second, third, and fourth gate control signals.

In various embodiments, the pixel further includes a first deep insulation trench on a first side of the substrate; and a second deep insulation trench on a second side of the substrate, wherein the first and second deep insulation trenches are configured to create a pinning potential at the substrate to deplete the substrate.

In various embodiments, the first vertical gate and the second vertical gate are configured to be activated alternatively using the first gate control signal and the second gate control signal, wherein the first gate control signal is a complement of the second gate control signal at a given time, and wherein the pixel is configured to determine an indirect time of flight (iToF).

In various embodiments, the first vertical gate and the second vertical gate are configured to be deactivated simultaneously for a first period of time and the first vertical gate or the second vertical gate to be activated for a second period of time using the first and second gate control signals, and wherein the pixel is configured to provide two-dimensional imaging.

In various embodiments, a pixel is provided. The pixel may include a substrate configured to generate one or more carriers in response to an incident light beam; a first vertical gate and a second vertical gate disposed inside the substrate, wherein the first and second vertical gates are configured to direct the one or more carriers to a first capacitor or a second capacitor; a first vertical gate input electronically coupled to the first vertical gate and configured to receive a first gate control signal; and a second vertical gate input electronically coupled to the second vertical gate and configured to receive a second gate control signal, wherein the first and second vertical gates are configured to direct the one or more carriers to the first capacitor or the second capacitor using the first and second gate control signals.

In various embodiments, the first vertical gate is configured to be activated using the first gate control signal and direct the one or more carriers to the first capacitor when activated; and the second vertical gate is configured to be activated using the second gate control signal and direct the one or more carriers to the second capacitor when activated.

In various embodiments, the first vertical gate is deactivated when the second vertical gate is activated; and the second vertical gate is deactivated when the first vertical gate is activated. In various embodiments, the first and second gate control signals include periodic waveforms and are complements of each other.

A method is provided in accordance with various embodiments of the present disclosure. The method may include disposing a first vertical gate and a second vertical gate inside a substrate, wherein the first and second vertical gates are configured to direct one or more carriers to a first sensing node or a second sensing node, wherein the one or more carriers are generated inside the substrate in response to an incident light beam; configuring a first vertical gate input to receive a first gate control signal, wherein the first vertical gate input is electronically coupled to the first vertical gate; and configuring a second vertical gate input to receive a second gate control signal, wherein the second vertical gate input is electronically coupled to the second vertical gate, wherein the first and second vertical gates are configured to direct the one or more carriers to a first sensing node or a second sensing node using the first and second gate control signals.

In various embodiments, the method includes configuring the first vertical gate to be activated using the first gate control signal and direct the one or more carriers to the first sensing node when the first vertical gate is activated; and configuring the second vertical gate to be activated using the second gate control signal and directing the one or more carriers to the second sensing node when the second vertical gate is activated.

In various embodiments, the method includes configuring the first vertical gate to be deactivated when the second vertical gate is activated; and configuring the second vertical gate to be deactivated when the first vertical gate is activated. In various embodiments, the first and second gate control signals include periodic waveforms and are complements of each other.

In various embodiments, the method includes disposing a third vertical gate inside the substrate; disposing a fourth vertical gate inside the substrate, wherein the first, second, and fourth vertical gates are configured to direct the one or more carriers to the first sensing node or the second sensing node; electronically coupling a third gate input to the third vertical gate to receive a third gate control signal; electronically coupling a fourth gate input to the fourth vertical gate to receive a fourth gate control signal; and directing the one or more carriers to the first sensing node or the second sensing node using the first, second, third, or fourth gate control signals.

In various embodiments, the method includes disposing a first deep insulation trench on a first side of the substrate; and disposing a second deep insulation trench on a second side of the substrate, wherein the first and second deep insulation trenches are configured to create a pinning potential at the substrate to deplete the substrate.

In various embodiments, the method includes activating the first vertical gate and the second vertical gate alternatively using the first gate control signal and the second gate control signal, wherein the first gate control signal is a complement of the second gate control signal at a given time.

In various embodiments, the method includes electronically coupling the first sensing node with a first supplemental capacitor; electronically coupling the second sensing node with a second supplemental capacitor; and configuring the first and second supplemental capacitors to determine an indirect time of flight or a two-dimensional density image using a first charge values of the first supplemental capacitor and a second charge value of the second supplemental capacitor.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF SUMMARY OF THE DRAWINGS

Having thus described certain example embodiments of the present disclosure in general terms, reference will now be made to the accompanying drawings, which are not necessarily drawn to scale, and wherein:

FIG. 1 is a schematic diagram illustrating an iToF determination system.

FIG. 2 is a schematic diagram illustrating a pixel.

FIG. 3 is a schematic diagram illustrating a pixel in accordance with various embodiments of the present disclosure.

FIG. 4 is a schematic diagram illustrating an operation of a pixel in accordance with various embodiments of the present disclosure.

FIG. 5A is a schematic diagram illustrating a pixel in accordance with various embodiments of the present disclosure.

FIG. 5B is a schematic diagram illustrating a pixel in accordance with various embodiments of the present disclosure.

FIG. 5C is a schematic diagram illustrating a pixel in accordance with various embodiments of the present disclosure.

FIG. 5D is a schematic diagram illustrating a pixel in accordance with various embodiments of the present disclosure.

FIG. 5E is a schematic diagram illustrating a pixel in accordance with various embodiments of the present disclosure.

FIG. 5F is a schematic diagram illustrating a pixel in accordance with various embodiments of the present disclosure.

FIG. 6 is a flowchart illustrating a method in accordance with various embodiments of the present disclosure.

FIG. 7 is a flowchart illustrating a method in accordance with various embodiments of the present disclosure.

FIG. 8 illustrates an example computing apparatus in accordance with one or more embodiments of the present disclosure.

### DETAILED DESCRIPTION

Embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

The phrases “in one embodiment,” “according to one embodiment,” “in some embodiments,” “In various embodiments” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

The term “electronically coupled,” “electronically coupling,” “electronically couple,” “in communication with,” “in electronic communication with,” or “connected” in the present disclosure refers to two or more elements or components being connected through wired means and/or wireless means, such that signals, voltage/current, data and/or information may be transmitted to and/or received from these elements or components.

Various embodiments of the present disclosure are directed to improved systems, apparatuses, products, and methods for light detection for example by using improved light detection systems. In various embodiments, the light detection system may be used in 3D imaging, for example using indirect Time of Flight (iToF) measurement.

In 3D imaging, a distance to an object may be determined. An approach to measure a distance to an object is Time of Flight (ToF) measurement. In ToF systems, a time of propagation of a light beam from an emitter to an object and back to a detector is measured. Using, the speed of light and the propagation time, the distance to the object may be measured.

In indirect Time of Flight (iToF) systems, the distance to an object is measured indirectly using a phase shift in the received light beam with respect to the emitted light beam.

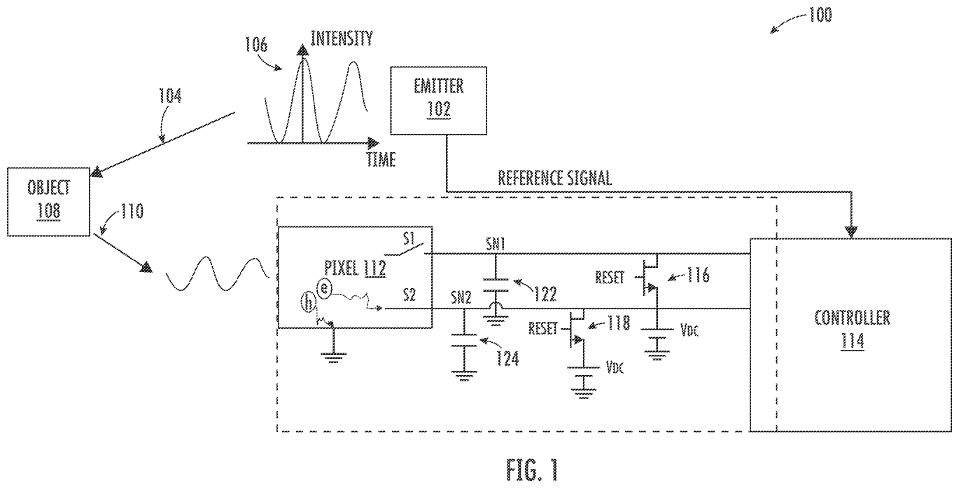

Referring now to FIG. 1 a schematic diagram illustrating an indirect time of flight (iToF) measurement system 100 is provided. The iToF measurement system 100 includes an emitter 102 configured to emit a light beam 104 having for example a sinusoidal wave 106. In an example, the emitted light beam 104 may be an intensity modulated continuous wave. The emitted light beam may be reflected from an object 108. The reflected light beam 110 will be detected by a pixel 112. In various embodiments, the pixel 112 is a light detecting pixel.

To determine a phase shift between the reflected light beam and the emitted light beam, the pixel 112 may reconstruct a sine wave of the reflected light beam 110 after it is detected by the pixel.

To reconstruct the sine wave, the pixel 112 samples the detected light beam. When the light beam is received by the pixel 112, the pixel generates electron carriers (e) and holes (h). The carriers are sampled using the switches S1 and S2 and are directed to a corresponding sensing node SN1 or SN2 for detection.

The detected carriers at the sensing nodes SN1 and SN2 charge a corresponding capacitor. For example, the sensing node SN1 charges first capacitor 122 and the sensing node SN2 charges the second capacitor 124. A controller 114 may compare the charges stored at the capacitors to reconstruct the phase value of the reflected light beam.

The sensing nodes SN1 and SN2 may be floating nodes and a voltage of the sensing nodes may need to be reset after each detection cycle to prepare for another acquisition of charges and measurement. The switches 116 and 118 may reset the voltage to VDC using the Reset signals.

In some examples, emitted light beams may be in the near infrared (NIR) wavelength range having a wavelength in the range of 800-1100 nm, for example 940 nm. In some examples, emitted light beams may be in the short-wave infrared (SWIR) wavelength range having a wavelength in the range of 1100 nm-3000 nm. Therefore, a suitable material in pixel 112 may be used to detect light beams in the corresponding wavelength range. For example, silicon has a good absorption in the NIR wavelength range and may be used in pixel 112 used for iToF and other imaging systems. Other materials such as Ge, InGaAs may be used in the SWIR wavelength range.

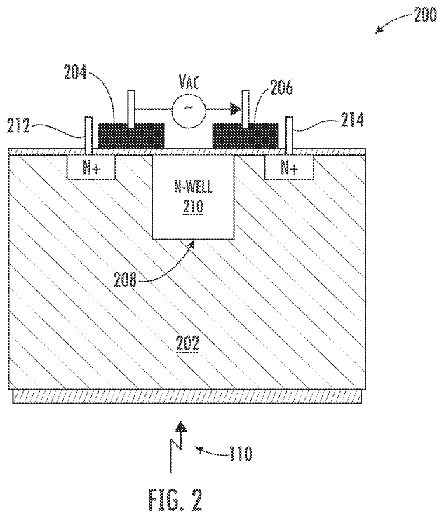

Referring now to FIG. 2 a schematic diagram illustrating a pixel 200 is provided in accordance with various embodiments that have been used. The pixel 200 may include a substrate 202. In various embodiments, the substrate 202 is a silicone substrate. The pixel 200 includes a P-N junction 208 at the center of the pixel between a first planar gate 204 and a second planar gate 206. The P-N junction 208 may be created for example by an N-well 210. The N-well 210 may be an N implanted zone at approximately the center of the pixel 200.

As the light beam is incident on the substrate 202, carriers are generated in the substrate 202. The P-N junction 208 creates an electrostatic potential gradient that transfers the carriers to the top of the pixel. By toggling between activation of the first planar gate 204 and the second planar gate 206, the charges are driven to the first sensing node 212 or the second sensing node 214. The first and second planar nodes may be activated using an AC signal VAC.

The first and second sensing nodes may be electronically coupled to an N+ region of the semiconductor. The N+ region may have an N type impurity dopant with high concentration. In an example, the N+ region may reduce contact resistance to the sensing node. For example, the N+ region may be an N fuse diffusion made by Arsenic or phosphorus doping.

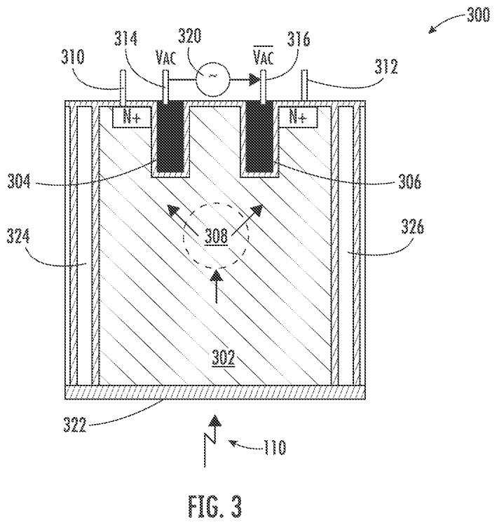

Referring now to FIG. 3 a schematic diagram illustrating a pixel 300 is provided in accordance with various embodiments of the present disclosure. In various embodiments, the pixel 300 includes a substrate 302. The substrate 302 may be configured to generate one or more carriers in response to an incident light beam, for example the reflected light beam 110. In various embodiments, pixel 300 includes a transparent layer 322 at the surface of the substrate 302 where the substrate is configured to absorb the incident light beam. The transparent layer 322 may include any of an anti-reflective layer, lens, micro lens array, etc.

In various embodiments, the pixel 300 includes a first vertical gate 304 and a second vertical gate 306 disposed inside the substrate. In various embodiments, the first vertical gate 304 and the second vertical gate 306 are implanted in the substrate 302. The first vertical gate 304 and the second vertical gate 306 may be deep trenches disposed inside the substrate 302.

In example embodiments, when operating in the NIR wavelength range, the height of the substrate may be between 5-12 micrometers. In example embodiments, the depth of the first vertical gate 304 and the second vertical gate 306 may be between 0.3 and 2 micrometers for example 1 micrometer. In example embodiments, if a material other than silicon with higher absorption is used, the height of the substrate may be smaller. In various embodiments, generally the height of the vertical gate may be between around 5% to 30% of the substrate height.

In various embodiments, the first and second vertical gates are used for an efficient transfer of the carriers from the substrate 302 to a first sensing node 310 and a second sensing node 312.

In various embodiments, the first vertical gate 304 and the second vertical gate 306 are activated using a first gate control signal applied to a first vertical gate input 314 and a second gate control signal applied to a second vertical gate input 316. In various embodiments, the first and second vertical gates are configured to direct the one or more carriers to the first sensing node 310 or the second sensing node 312 using the first and second gate control signals.

For example, by alternatively activating the first and second vertical gates, an electrical potential is created in the substrate 302 and the one or more carriers are directed from a lower zone of the substrate 302 to a higher zone, for example zone 308 of the substrate, closer to the vertical gates. In various embodiments, a potential in zone 308 is also generated due to an adequate doping profile of substrate 302 and also by potentials applied to deep insulation trenches 324 and 326 as further described below. In various embodiments, when the first vertical gate 304 is activated, the carriers are directed in a direction towards the first vertical gate and to the first sensing node. When the second vertical gate 306 is activated, the carriers are directed in a direction towards the second vertical gate and to the second sensing node.

In example embodiments, the pixel 300 directs the carriers to the corresponding sensing node without a need for the P-N junction created by a deep N implantation for example the N-well as described with respect to pixel 200. By not requiring the N-well, various embodiments provide a reduction of process variability in manufacturing the pixel while increasing transfer efficiency of carriers to the sensing nodes. Reducing process variability in manufacturing a pixel may reduce mismatch and/or inconsistencies among various pixels in a pixel array or matrix.

In various embodiments, the first vertical gate is deactivated when the second vertical gate is activated, and the second vertical gate is deactivated when the first vertical gate is activated. The vertical gates may be activated using periodic signals generated by a voltage and/or current source 320. The source 320 may generate the first gate control signal and the second gate control signal. The first and second control signals may have periodic waveforms and may be complements of each other. For example, at a given time, the first gate control signal applied to the first vertical gate input may have a high value and the second gate control signal applied to the second vertical gate input would have a low value.

In example embodiments, for example as compared to pixel 200, the pixel 300 provides a more homogenous electrostatic potential in the substrate with a gradient towards the vertical gate and then towards the corresponding sensing node when each vertical gate is activated.

In various embodiments, the first and second sensing nodes are floating junctions, and their resulting voltage will vary as carriers are directed to each sensing nodes. This may be because each sensing node has an intrinsic capacitance, and when the carriers are transferred to the corresponding sensing node, a charge of the intrinsic capacitance and its corresponding voltage may change. In various embodiments, the intrinsic capacitance of each sensing node is supplemented using an external capacitance. In various embodiments, when the pixel 300 functions as an iToF pixel, the charges accumulated on each sensing node, and/or the supplemental capacitor electronically coupled in parallel to the sensing node, is measured for the iToF determination as for example described with reference to FIG. 1.

In various embodiments, by toggling between the activation of the vertical gates, the pixel alternates between charge collection at the first and second sensing nodes. By doing so over a period of time, the controller 114 may integrate the first charge collection on the first sensing node and the second charge collection at the second sensing node. Using the integration values, a reconstruction of the phase shift that the beam has suffered when it was reflected from an object and received by the Pixel is determined.

In various embodiments, by alternating faster between charge collections at different sensing nodes, the pixel 300 may provide a more precise measurement of the phase shift of the reflected signal the iToF determination. In example embodiments, pixel 300 enables higher frequency for activation and deactivation of the vertical gates and therefore a faster alternation between charge collections at the first and second sensing nodes for a more precise iToF measurement as for example compared with pixel 200.

In various embodiments, by etching the vertical gates deep in the substrate in the pixel 300, a higher driving potential is created in the substrate volume, therefore the carriers are directed to the sensing node more efficiently with a lower amplitude requirement for the gate control signals.

In various embodiments, the pixel 300 includes a first deep insulation trench 324 and a second deep insulation trench 326. The deep insulation trenches may extend as deep as the substrate. In various embodiments, the substrate may be fully surrounded with multiple deep insulation trenches.

In various embodiments, the first deep insulation trench 324 and the second deep insulation trench 326 create a pinning potential at the substrate to deplete the substrate. In various embodiments, DC voltage signals may be applied to the deep insulation trenches to create the pinning potential.

In example embodiments, using the vertical gates and the deep insulation trenches, a uniform electrostatic field may be generated in the substrate from the bottom to the top, in order to direct the carriers to the top, and then to the right direction near the top to the right sensing node depending on which vertical gate is activated.

In various embodiments, a lateral gradient of electrostatic field is created by the deep insulation trenches to deplete the substrate volume and a vertical gradient of electrostatic field is created by the vertical gates upwards and to a sensing node corresponding to a vertical gate that is activated at a given time.

In various embodiments, the deep insulation trenches and the vertical gates are made with a dielectric liner (e.g. SiO2 or HK materials, Hf02, Al2O3, etc.) then filled with a conductive material (e.g. doped poly-silicon or metal such as Al, W, Ag, etc.). In various embodiments, the substrate is made from silicon, Ge, or InGaAs, etc., as previously described.

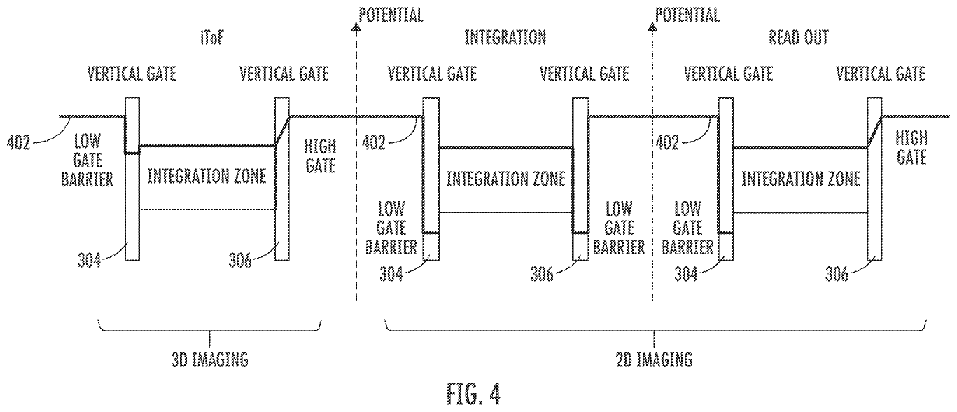

Referring now to FIG. 4 a schematic diagram illustrating operation examples of the pixel 300 in three-dimensional (3D) imaging or iToF measurement, and in two-dimensional (2D) imaging is provided in accordance with various embodiments of the present disclosure. As shown in FIG. 4, line 402 is a schematic illustration of an electrostatic potential level in the pixel 300 in accordance with various embodiments.

In various embodiments, the pixel 300 may operate in a 3D imaging or iToF mode. When in the iToF mode, the first vertical gate and the second vertical gate of the pixel may be configured to be activated alternatively using the first gate control signal and the second gate control signal. In various embodiments, the first control signal is a complement of the second control signal at a given time.

In various embodiments, when the first vertical gate is deactivated, it creates a low gate acting as a barrier between the carriers in an integration zone of the substrate (for example zone 308 in FIG. 3) and the first sensing node. In the iToF mode, when the first vertical gate is deactivated, the second vertical gate may be activated. When the second vertical gate is activated, it creates a high gate acting as a potential gradient directing the carriers to the second sensing node. By alternatively activating and deactivating the first and/or the second gate, when operating in the iToF mode, the pixel 300 alternatively directs the charges to the corresponding first or second sensing nodes.

In example embodiments, by not using a P-N junction or an N-well in the integration zone, the activation and/or deactivation of the first and second gates in the pixel 300 may be performed at higher frequency and using lower amplitude. Therefore, the accuracy of the measurement may increase, and a power consumption of the pixel may decrease.

In various embodiments, the pixel 300 may operate in a 2D imaging, for example using light intensity acquisition. When operating in 2D imaging, the first vertical gate and the second vertical gate may be configured to be deactivated simultaneously for a first period of time which may be referred to as the integration time. The first vertical gate or the second vertical gate may then be activated for a second period of time which may be referred to as the readout time. In various embodiments, vertical gates are activated and deactivated using the first and second gate control signals.

During the integration time, the first and second vertical gates may be deactivated, hence creating low gates acting as barriers between the carriers in an integration zone of the substrate (for example zone 308 in FIG. 3) and the first sensing node and the second sensing node. Hence, during the integration zone, charges are integrated in the integration zone. In various embodiments, the barrier created during the integration time may be a stronger barrier than the barrier created during the iToF mode, to allow for a larger accumulation of charges for 2D imaging.

During the readout time, any of the first or second vertical carriers may be activated. When a vertical gate is activated, it creates a high gate acting as a potential gradient directing the integrated carriers to the corresponding sensing node for a readout representing the captured 2D image in the pixel.

In example embodiments, by not using P-N junction or an N-well in the integration zone, a larger integration of carriers may be possible in the integration zone. Using the vertical gates that are deeply implanted in the pixel may allow providing gates with a very low biasing, therefore creating significant low gate barriers allowing for storing a significant number of carriers in the volume of the pixel.

Therefore, in example embodiments, by simply varying a biasing condition of the vertical gates using the gate control signals, the pixel may operate in the 3D or 2D imaging modes.

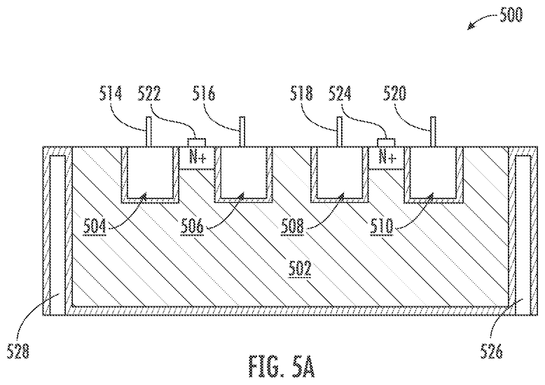

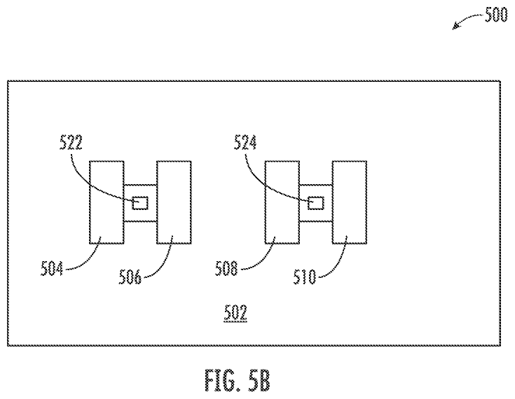

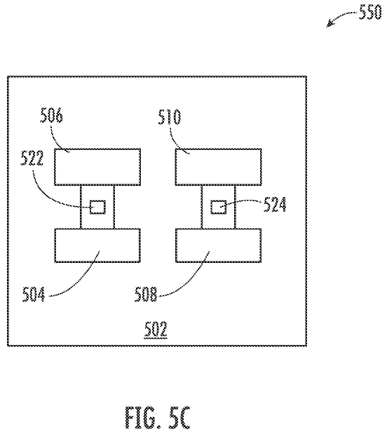

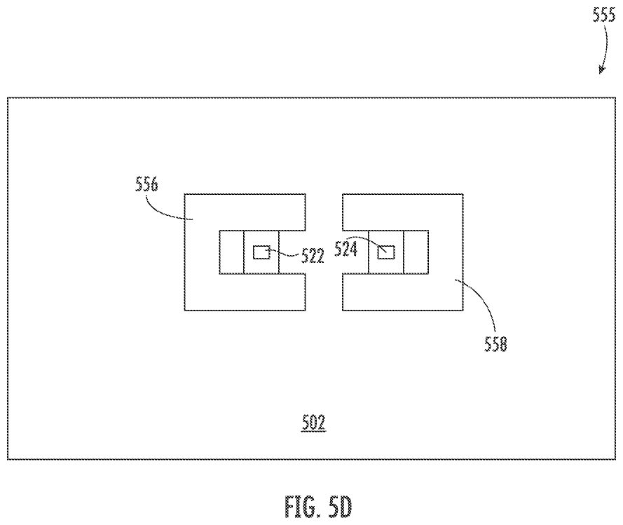

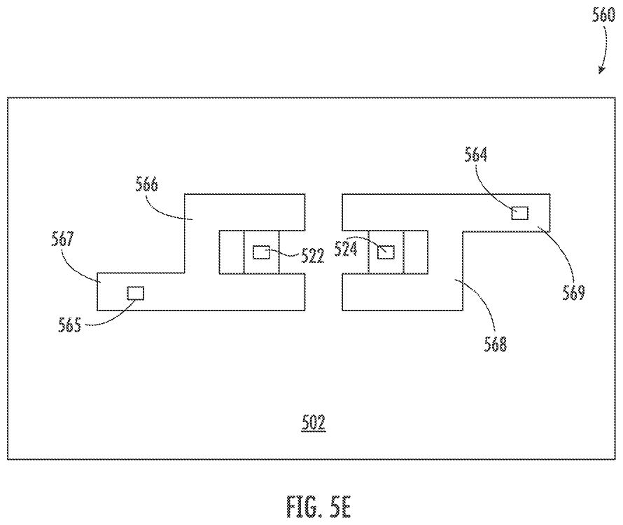

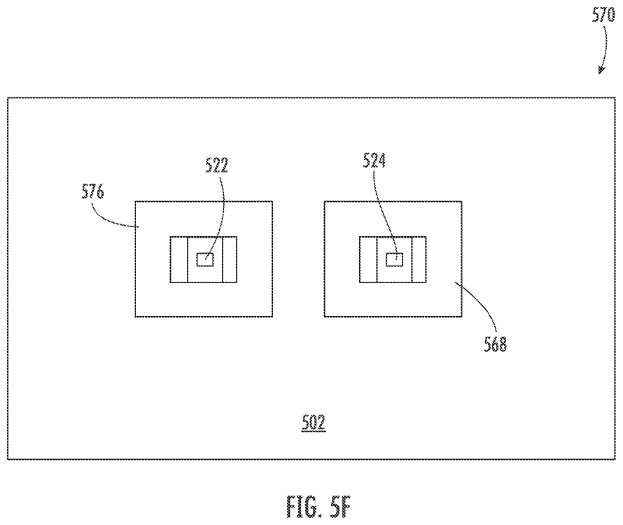

Referring now to FIG. 5A a schematic diagram illustrating a pixel 500 is provided in accordance with various embodiments of the present disclosure. In various embodiments, the pixel 500 includes a first vertical gate 504, a second vertical gate 506, a third vertical gate 508, and a fourth vertical gate 510 disposed inside a substrate 502. In various embodiments, the vertical gates are implanted in the substrate 502. The vertical gates may be deep trenches disposed inside the substrate 502.

In various embodiments, the first, second, third, and fourth vertical gates are configured to direct one or more carriers generated inside the substrate 502, in response to an incident light beam, to a first sensing node 522 or a second sensing node 524. In various embodiments, the first and second vertical gates are configured to direct the one or more carriers to the first sensing node 522 and the third and fourth vertical gates are configured to direct the one or more carriers to the second sensing node 524.

In various embodiments, the first sensing node may be disposed in proximity to the first and second vertical gates and the second sensing node may be disposed in proximity to the third and fourth vertical gates. For example, the first sensing node may be disposed between the first and second vertical gates and the second sensing node may be disposed between the third and fourth vertical gate.

In various embodiments, the first vertical gate is electronically coupled to a first vertical gate input 514 and is configured to receive a first gate control signal. In various embodiments, the second vertical gate is electronically coupled to a second vertical gate input 516 and is configured to receive a second gate control signal. In various embodiments, a third gate input 518 electronically coupled to the third vertical gate and configured to receive a third gate control signal. In various embodiments, a fourth gate input 520 is electronically coupled to the fourth vertical gate and configured to receive a fourth gate control signal. FIG. 5B is a schematic diagram illustrating arrangement of the components from a top view.

In various embodiments, the first, second, third, and fourth vertical gates are configured to direct the one or more carriers to the first sensing node or the second sensing node using the first, second, third, and fourth gate control signals. In example embodiments, when the first and/or second vertical gates are activated using the first and/or second gate control signals, the carriers are directed to the first sensing node. In example embodiments, when the third and/or fourth vertical gates are activated using the third and/or fourth gate control signals, the carriers are directed to the second sensing node.

In various embodiments, the first and second vertical gates may be activated and deactivated similarly and at the same frequency as the third and fourth vertical gates. In various embodiments, each vertical gate may be activated and/or deactivated in various frequencies and/or with a time shift with respect to each other to provide for a higher sampling rate of a reflected optical beam in an iToF determination.

In various embodiments, the pixel 500 may include a first deep insulation trench 526 on a first side of the substrate 502 and a second deep insulation trench 528 on a second side of the substrate. The first and second deep insulation trenches may be configured to create a pinning potential at the substrate to deplete the substrate.

In various embodiments, any number of two or more vertical gates and/or any arrangement of the vertical gates with respect to the first and second sensing nodes may be used. For example, the vertical gates and the sensing nodes and their corresponding N+ regions may be arranged in a single line as shown in FIG. 5A. In various embodiments, a first group of the vertical gates direct carriers from the substrate to the first sensing nodes and a second group of vertical gates direct the carriers to the second sensing nodes. The first sensing node may be disposed in proximity to the first group of the vertical gates and the second sensing node may be disposed in proximity of the second group of the vertical gates. For example, the first and the second vertical gates may be the first group of the vertical gates and the third and fourth vertical gates may be the second group of the vertical gates.

For example, referring to FIG. 5C a schematic diagram 550 illustrating arrangement of the vertical gates with respect to the sensing nodes in a pixel is provided in accordance with various embodiments of the present disclosure. The schematic diagram 550 illustrates the arrangement of components from a top view.

In various embodiments, the first vertical gate 504, the second vertical gate 506, and the first sensing node 522, and the N+ region corresponding to the first node may be arranged in a first line and the third vertical gate 508, the fourth vertical gate 510, and the second sensing node 524 and the N+ region corresponding to the second sensing node may be arranged in a second line. In various embodiments, the first line and the second line may be approximately parallel.

In various embodiments, when more than one vertical gate corresponds to each sensing node, as for example shown by FIGS. 5A-5C, at least one of the vertical gates corresponding to each sensing node may be electronically coupled to and biased with a same DC bias voltage. The other vertical gates corresponding to the sensing nodes may be operated using the complementary and variable gate control signals as previously described. For example, vertical gates 504 and 510 may be electronically coupled to and biased with a same DC bias and vertical gates 506 and 508 may be electronically coupled to and biased with complementary AC bias signals. In example embodiments, the DC bias signal, as applied to at least one of the vertical gates, may further facilitate directing the one or more carriers from a lower zone of the substrate (e.g. zone 302) to a higher zone of the substrate (e.g. zone 308), closer to the vertical gates and the sensing nodes.

In various embodiments, the vertical gates may have various cross-sectional shapes. For example, at least one of or all of the first, second, third, or forth vertical gates may have various cross section shapes around the corresponding sensing node and may fully or partially surround the corresponding sensing node. In various embodiments, at least one or all of the vertical gates may partially surround the sensing node, for example by having a C cross sectional shape, an F cross sectional shape, or an h cross sectional shape. In various embodiments, at least one or all of the vertical gates may fully surround the corresponding sensing node for example by having a circular (e.g., an O) cross sectional shape or a b cross sectional shape surrounding the corresponding sensing node. In various embodiments, when more than one vertical gate correspond to a sensing node, the vertical gates fully or partially surrounding a sensing nodes may be concentric of off-centered with respect to each other.

For example, referring now to FIG. 5D a schematic diagram 555 illustrating a first vertical gate 556 and a second vertical gate 558 is provided in accordance with various embodiments of the present disclosure. As shown in FIG. 5D, the vertical gates may partially surround the sensing nodes 522 and 524. The vertical gates as shown in the example of FIG. 5D have cross-sections with square like shapes partially surrounding the sensing nodes, however the vertical gates may have rounded cross section shapes such as a partial circle (e.g. a C shape) or partial oval shapes.

For example, referring now to FIG. 5E a schematic diagram 560 illustrating a first vertical gate 566 and a second vertical gate 568 is provided in accordance with various embodiments of the present disclosure. As shown in FIG. 5E, the vertical gates may partially surround the sensing nodes 522 and 524 and have extensions 567 and 569 for example for electronically coupling to the first vertical gate input 565 and second vertical gate input 564, respectively. The vertical gates as shown in the example of FIG. 5E have cross-sections with square like shapes partially surrounding the sensing nodes, however the vertical gates may have rounded cross section shapes partially surrounding the sensing nodes such as a partial circle or partial oval shapes.

For example, referring now to FIG. 5F a schematic diagram 570 illustrating a first vertical gate 576 and a second vertical gate 578 is provided in accordance with various embodiments of the present disclosure. As shown in FIG. 5F, the vertical gates may fully surround the sensing nodes 522 and 524. The vertical gates as shown in the example of FIG. 5F have cross-sections with square like shapes fully surrounding the sensing nodes, however the vertical gates may have rounded cross section shapes such as a circular (e.g. a ring) or oval shapes.

In example embodiments, the vertical gates provided herein may have a higher driving capability in the whole volume of the pixel substrate than planar gates. For example, a small difference of electrostatic potential between the vertical gates may provide a transfer of charges to the corresponding sensing node, hence increasing efficiency of the pixel by requiring a lower amplitude of the gate control signal needed to operate the pixel.

In example embodiments, using vertical gates and their higher driving capability may make it possible to increase the volume of the substrate without degrading the frequency performance of the of the pixel. For example, using vertical gates increases the quantum efficiency (QE) of the pixel by increasing the thickness of the volume of the substrate silicon without degrading the performance because of the uniform and strong electrostatic field gradient generated by the vertical gates and a strong driving force on carriers caused by it. In example embodiments, the QE may represent a ratio of the total measured carriers by the sensing nodes of the pixel over the total incident photons on the pixel. In example embodiments, using vertical gates also may maintain a high demodulation contrast (DMC) in the pixel. DMC may indicate an estimation of a rate of collection and/or detection of photons by the pixel at the operation frequency.

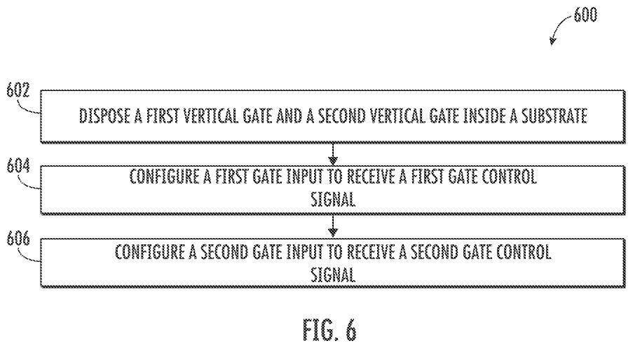

Referring now to FIG. 6 a diagram illustrating a method 600 is provided in accordance with various embodiments of the present disclosure. In various embodiments, the method 600 may be used for fabricating and/or preparing a light detecting pixel, for example pixel 300 as described above. In various embodiments, at step 602, the method 600 disposes a first vertical gate 304 and a second vertical gate 306 inside a substrate 302. In various embodiments, the first and second vertical gates are configured to direct the one or more carriers to a first sensing node 310 or a second sensing node 312. In various embodiments, the one or more carriers are generated inside the substrate in response to an incident light beam on the pixel which may be the reflected light beam 110.

In various embodiments, at step 604, the method 600 configures a first vertical gate input 314 to receive a first gate control signal. The first vertical gate input may be electronically coupled to the first vertical gate.

In various embodiments, at step 606, the method 600 configures a second vertical gate input 316 to receive a second gate control signal. The second vertical gate input may be electronically coupled to the second vertical gate. In various embodiments, the first and second vertical gates are configured to direct the one or more carriers to the first sensing node or the second sensing node using the first and second gate control signals. In example embodiments, the first and second sensing nodes have intrinsic capacitance and are the first and second sensing nodes. In various embodiments, the capacitance of the first and second sensing node are supplemented with external capacitors as for example illustrated in FIG. 1 and described above.

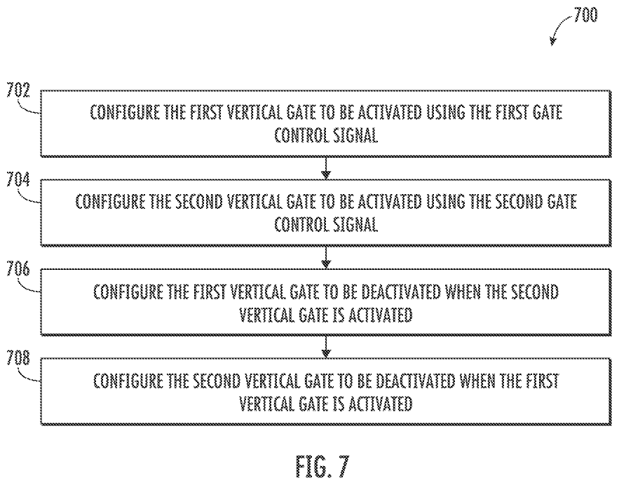

Referring now to FIG. 7 a schematic diagram illustrating a method 700 is provided in accordance with various embodiments of the present disclosure. In various embodiments, the method 700 may be used for fabricating and/or preparing a light detecting pixel, for example pixel 300 as described above. In various embodiments, at step 702, the method 700 configures the first vertical gate to be activated using the first gate control signal and direct the one or more carriers to the first sensing node when the first vertical gate is activated.

In various embodiments, at step 704, the method 700 configures the second vertical gate to be activated using the second gate control signal and directing the one or more carriers to the second sensing node when the second vertical gate is activated.

In various embodiments, at step 706, the method 700 configures the first vertical gate to be deactivated when the second vertical gate is activated. In various embodiments, at step 708, the method 700 configures the second vertical gate to be deactivated when the first vertical gate is activated. In various embodiments, the method 700 activates and deactivates the vertical gates using a periodic first gate control signal and a periodic second gate control signal, where the first and second gate control signals are complements of each other as described above. Therefore, in various embodiments, first and second control signals include periodic waveforms and are complements of each other.

In various embodiments, the method 700 may include disposing a third vertical gate inside the substrate, and disposing a fourth vertical gate inside the substrate, wherein the first, second, and fourth vertical gates are configured to direct the one or more carriers to the first sensing node or the second sensing node. In various embodiments, the method 700 may include electronically coupling a third gate input to the third vertical gate to receive a third gate control signal, and electronically coupling a fourth gate input to the fourth vertical gate to receive a fourth gate control signal. In various embodiments, the method 700 may include directing the one or more carriers to the first sensing node or the second sensing node using the first, second, third, or fourth gate control signals.

In various embodiments, the method 700 may include disposing a first deep insulation trench on a first side of the substrate and disposing a second deep insulation trench on a second side of the substrate, wherein the first and second deep insulation trenches are configured to create a pinning potential at the substrate to deplete the substrate.

In various embodiments, the method 700 may include activating the first vertical gate and the second vertical gate alternatively using the first gate control signal and the second gate control signal, wherein the first control signal is a complement of the second control signal at a given time. In various embodiments, the method 700 may include determining the indirect time of flight using a first charge values of the first intrinsic capacitance of the first sensing node and the second charge value of the intrinsic capacitance of the second sensing node.

In various embodiments, the method 700 may include electronically coupling the first sensing node with a first supplemental capacitor and electronically coupling the second sensing node with a second supplemental capacitor, as for example illustrated with reference to FIG. 1. In various embodiments, the method 700 may include configuring the first and second supplemental capacitors to determine an indirect time of flight or a two-dimensional density image using a first charge values of the first supplemental capacitor and a second charge value of the second supplemental capacitor.

It should be readily appreciated that the embodiments of the systems, apparatus, and methods described herein may be configured in various additional and alternative manners in addition to those expressly described herein.

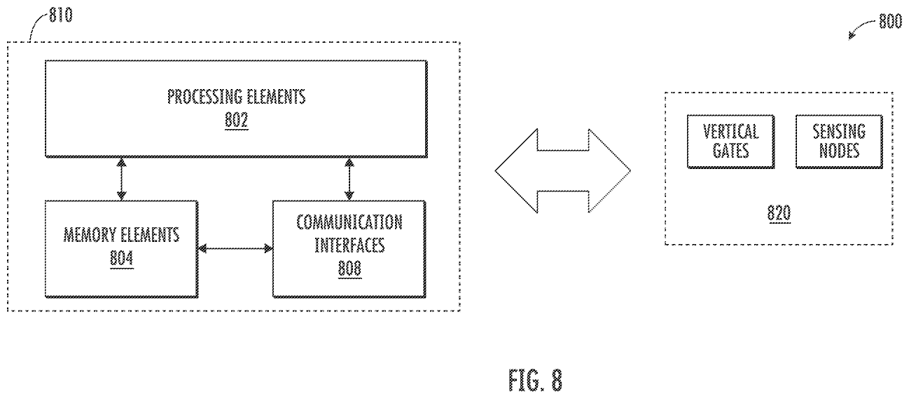

FIG. 8 illustrates an example light detection system 800 in accordance with one or more embodiments of the present disclosure.

The light detection system 800 can include a computing apparatus 810 and/or one or more light detection pixels 820 communicatively coupled to the computing apparatus 810 using one or more wired and/or wireless communication techniques. In general, the terms computing apparatus, computer, system, device, entity, and/or similar words used herein interchangeably can refer to, for example, one or more computers, computing entities, desktops, mobile phones, tablets, notebooks, laptops, distributed systems, kiosks, input terminals, servers or server networks, blades, gateways, switches, processing devices, processing entities, controllers, control systems, set-top boxes, relays, routers, network access points, base stations, the like, and/or any combination of devices or entities adapted to perform the functions, operations, and/or processes described herein. Such functions, operations, and/or processes can include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably. The computing apparatus 810 can include any computing device including, for example, a light detection processing apparatus configured to perform one or more steps/operations of one or more light detection techniques described herein. In some examples, the computing apparatus 810 may determine an indirect time of flight (iToF) as described herein. In some examples, the computing apparatus 810 may detect a 2D image as described herein. In some embodiments, the computing apparatus 810 can include and/or be in association with one or more mobile device(s), desktop computer(s), laptop(s), server(s), cloud computing platform(s), and/or the like. In some example embodiments, the computing apparatus 810 can be configured to receive and/or transmit light detection instructions, data, and/or the like between the one or more light detection pixels 820 to perform one or more steps/operations of one or more light detection techniques described herein.

The computing apparatus 810 can include, or be in communications with, one or more processing elements 802 (also referred to as processors, processing circuitry, digital circuitry, and/or similar terms used herein interchangeably) that communicate with other elements within the computing apparatus 810 via a bus, for example. As will be understood, the processing element 802 can be embodied in a number of different ways.

For example, the processing element 802 can be embodied as one or more complex programmable logic devices (CPLDs), microprocessors, multi-core processors, coprocessing entities, application-specific instruction-set processors (ASIPs), microcontrollers, and/or controllers. Further, the processing element 802 can be embodied as one or more other processing devices or circuitry. The term circuitry can refer to an entirely hardware embodiment or a combination of hardware and computer program products. Thus, the processing element 802 can be embodied as integrated circuits, application specific integrated circuits (ASICs), field programmable gate arrays (FPGAs), programmable logic arrays (PLAs), hardware accelerators, digital circuitry, and/or the like.

As will therefore be understood, the processing element 802 can be configured for a particular use or configured to execute instructions stored in volatile or non-volatile media or otherwise accessible to the processing element 802. As such, whether configured by hardware or computer program products, or by a combination thereof, the processing element 802 can be capable of performing steps or operations according to embodiments of the present disclosure when configured accordingly.

In one embodiment, the computing apparatus 810 can further include, or be in communication with, one or more memory elements 804. The one or more memory elements 804 can include non-volatile and/or volatile media. The memory elements 804, for example, can include non-volatile media (also referred to as non-volatile storage, memory, memory storage, memory circuitry and/or similar terms used herein interchangeably). In one embodiment, the non-volatile storage or memory can include one or more non-volatile storage or memory media, including, but not limited to, hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like.

As will be recognized, the non-volatile storage or memory media can store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably can refer to a collection of records or data that is stored in a computer-readable storage medium using one or more database models, such as a hierarchical database model, network model, relational model, entity-relationship model, object model, document model, semantic model, graph model, and/or the like.

In addition, or alternatively, the memory elements 804 can include volatile memory. For example, the computing apparatus 810 can further include, or be in communication with, volatile media (also referred to as volatile storage memory, memory storage, memory circuitry and/or similar terms used herein interchangeably). In one embodiment, the volatile storage or memory can also include one or more volatile storage or memory media, including, but not limited to, RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like.

As will be recognized, the volatile storage or memory media can be used to store at least portions of the databases, database instances, database management systems, data, applications, programs, program modules, scripts, source code, object code, byte code, compiled code, interpreted code, machine code, executable instructions, and/or the like being executed by, for example, the processing element 802. Thus, the databases, database instances, database management systems, data, applications, programs, program modules, scripts, source code, object code, byte code, compiled code, interpreted code, machine code, executable instructions, and/or the like can be used to control certain aspects of the operation of the computing apparatus 810 with the assistance of the processing element 802 and operating system.

As indicated, in one embodiment, the computing apparatus 810 can also include one or more communication interfaces 808 for communicating with various computing entities, such as by communicating data, content, information, and/or similar terms used herein interchangeably that can be transmitted, received, operated on, processed, displayed, stored, and/or the like. Such communication can be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing apparatus 810 can be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.9 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

The light detection system 800 can include input/output circuitry for communicating with one or more users or other systems or devices. The input/output circuitry, for example, can include one or more interfaces for providing and/or receiving information from one or more users or other systems or devices of the light detection system 800 or otherwise. The input/output circuitry can be configured to receive user input or input from various other systems or devices through one or more of the interfaces of the light detection system 800.

### CONCLUSION

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

While this detailed description has set forth some embodiments of the present disclosure, the appended claims cover other embodiments of the present disclosure which differ from the described embodiments according to various modifications and improvements.

1. A pixel, comprising:
a substrate configured to generate one or more carriers in response to an incident light beam;
a first vertical gate and a second vertical gate disposed inside the substrate, wherein the first and second vertical gates are configured to direct the one or more carriers to a first sensing node or a second sensing node;
a first vertical gate input electronically coupled to the first vertical gate and configured to receive a first gate control signal; and
a second vertical gate input electronically coupled to the second vertical gate and configured to receive a second gate control signal, wherein the first and second vertical gates are configured to direct the one or more carriers to the first sensing node or the second sensing node using the first and second gate control signals.

2. The pixel of claim 1, wherein:
the first vertical gate is configured to be activated using the first gate control signal and direct the one or more carriers to the first sensing node when activated; and
the second vertical gate is configured to be activated using the second gate control signal and direct the one or more carriers to the second sensing node when activated.

3. The pixel of claim 2, wherein:
the first vertical gate is deactivated when the second vertical gate is activated; and
the second vertical gate is deactivated when the first vertical gate is activated.

4. The pixel of claim 3, wherein the first and second gate control signals include periodic waveforms and are complements of each other.

5. The pixel of claim 1, further comprising:
a third vertical gate disposed inside the substrate;
a fourth vertical gate disposed inside the substrate, wherein the first, second, third, and fourth vertical gates are configured to direct the one or more carriers to the first sensing node or the second sensing node;
a third gate input electronically coupled to the third vertical gate and configured to receive a third gate control signal; and
a fourth gate input electronically coupled to the fourth vertical gate and configured to receive a fourth gate control signal, wherein the first, second, third and fourth vertical gates are configured to direct the one or more carriers to the first sensing node or the second sensing node using the first, second, third, and fourth gate control signals.

6. The pixel of claim 1, further comprising:
a first deep insulation trench on a first side of the substrate; and
a second deep insulation trench on a second side of the substrate, wherein the first and second deep insulation trenches are configured to create a pinning potential at the substrate to deplete the substrate.

7. The pixel of claim 1, wherein the first vertical gate and the second vertical gate are configured to be activated alternatively using the first gate control signal and the second gate control signal, wherein the first gate control signal is a complement of the second gate control signal at a given time, and wherein the pixel is configured to determine an indirect time of flight (iToF).

8. The pixel of claim 1, wherein the first vertical gate and the second vertical gate are configured to be deactivated simultaneously for a first period of time and the first vertical gate or the second vertical gate to be activated for a second period of time using the first and second gate control signals, and wherein the pixel is configured to provide two-dimensional imaging.

9. A pixel comprising:
a substrate configured to generate one or more carriers in response to an incident light beam;
a first vertical gate and a second vertical gate disposed inside the substrate, wherein the first and second vertical gates are configured to direct the one or more carriers to a first capacitor or a second capacitor;
a first vertical gate input electronically coupled to the first vertical gate and configured to receive a first gate control signal; and
a second vertical gate input electronically coupled to the second vertical gate and configured to receive a second gate control signal, wherein the first and second vertical gates are configured to direct the one or more carriers to the first capacitor or the second capacitor using the first and second gate control signals.

10. The pixel of claim 9, wherein:
the first vertical gate is configured to be activated using the first gate control signal and direct the one or more carriers to the first capacitor when activated; and
the second vertical gate is configured to be activated using the second gate control signal and direct the one or more carriers to the second capacitor when activated.

11. The pixel of claim 10, wherein:
the first vertical gate is deactivated when the second vertical gate is activated; and
the second vertical gate is deactivated when the first vertical gate is activated.

12. The pixel of claim 11, wherein the first and second gate control signals include periodic waveforms and are complements of each other.

13. A method, comprising:
disposing a first vertical gate and a second vertical gate inside a substrate, wherein the first and second vertical gates are configured to direct one or more carriers to a first sensing node or a second sensing node, wherein the one or more carriers are generated inside the substrate in response to an incident light beam;
configuring a first vertical gate input to receive a first gate control signal, wherein the first vertical gate input is electronically coupled to the first vertical gate; and
configuring a second vertical gate input to receive a second gate control signal, wherein the second vertical gate input is electronically coupled to the second vertical gate, wherein the first and second vertical gates are configured to direct the one or more carriers to a first sensing node or a second sensing node using the first and second gate control signals.

14. The method of claim 13 comprising:
configuring the first vertical gate to be activated using the first gate control signal and direct the one or more carriers to the first sensing node when the first vertical gate is activated; and
configuring the second vertical gate to be activated using the second gate control signal and directing the one or more carriers to the second sensing node when the second vertical gate is activated.

15. The method of claim 14 comprising:
configuring the first vertical gate to be deactivated when the second vertical gate is activated; and
configuring the second vertical gate to be deactivated when the first vertical gate is activated.

16. The method of claim 15, wherein the first and second gate control signals include periodic waveforms and are complements of each other.

17. The method of claim 13 comprising:
disposing a third vertical gate inside the substrate;
disposing a fourth vertical gate inside the substrate, wherein the first, second, and fourth vertical gates are configured to direct the one or more carriers to the first sensing node or the second sensing node;
electronically coupling a third gate input to the third vertical gate to receive a third gate control signal;
electronically coupling a fourth gate input to the fourth vertical gate to receive a fourth gate control signal; and
directing the one or more carriers to the first sensing node or the second sensing node using the first, second, third, or fourth gate control signals.

18. The method of claim 13 comprising:
disposing a first deep insulation trench on a first side of the substrate; and
disposing a second deep insulation trench on a second side of the substrate, wherein the first and second deep insulation trenches are configured to create a pinning potential at the substrate to deplete the substrate.

19. The method of claim 13 comprising activating the first vertical gate and the second vertical gate alternatively using the first gate control signal and the second gate control signal, wherein the first gate control signal is a complement of the second gate control signal at a given time.

20. The method of claim 19 comprising:
electronically coupling the first sensing node with a first supplemental capacitor;
electronically coupling the second sensing node with a second supplemental capacitor; and
configuring the first and second supplemental capacitors to determine an indirect time of flight or a two-dimensional density image using a first charge values of the first supplemental capacitor and a second charge value of the second supplemental capacitor.
